(19) United States
(12) Patent Application Publication
(10) Pub. No.: US 2024/0007794 A1
(43) Pub. Date: Jan. 4, 2024

(54) DISTRIBUTED MODE LOUDSPEAKER WITH FREE MOTION HEAT SINK

(71) Applicant: Valcom, Inc., Roanoke, VA (US)

(72) Inventors: John W. Mason, Vero Beach, FL (US); Gary L. Rice, Roanoke, VA (US); Eric O. Townsend, Roanoke, VA (US); Kevin G. Lane, Salem, VA (US)

(21) Appl. No.: 18/216,532

(22) Filed: Jun. 29, 2023

Related U.S. Application Data
(60) Provisional application No. 63/356,838, filed on Jun. 29, 2022.

(51) Int. Cl. H04R 7/02; H05K 7/20

(52) U.S. Cl. CPC H04R 7/02; H05K 7/2039

(57) ABSTRACT

A Distributed Mode Loudspeaker (DML) assembly which includes a free motion heat sink module that provides for mechanical reinforcement to the exciter connection to help resist shear forces while not impinging on the ability of the exciter to oscillate the panel in the desired fashion. The panel may also be provided with a flexible sleeve which allows for customization of the panel from an aesthetic point of view as well as for the alteration of specific tone production capabilities of the panel without the need to alter the panel construction or to disconnect the exciter or heat sink.

### CROSS-REFERENCE TO RELATED APPLICATIONS

This application claims the benefit of U.S. Provisional Patent Application Ser. No. 63/356,838 filed Jun. 29, 2022, the entire disclosure of which is herein incorporated by reference.

### BACKGROUND OF THE INVENTION

### Field of the Invention

This disclosure relates to the field of loudspeaker housings and particularly to housings for Distributed Mode Loudspeakers (DMLs).

### Description of the Related Art

Issued on Feb. 19, 1878, United States Patent No. 200,521 is likely one of the more well known of Thomas Edison's many inventions. Directed to a “Phonograph or Speaking Machine” this patent is often identified as being to the first device for recording and replaying sounds. In that original phonograph, the mechanical movement produced by a sound was transferred to a cylinder of foil or other material by indenting the material an amount corresponding to the originally generated sound wave. To reproduce the sound, the indentations were used to move a spring which was connected to a thin diaphragm placed in a tube. As the diaphragm vibrated due to the motion of the spring through the indentions, sound was produced through the tube.

Nearly 150 years later, the same basic principles of loudspeaker operation are still used in most cone loudspeakers. While the spring has generally been replaced by sophisticated electromagnets and the pistonic motion and resultant pressure wave no longer rely on Edison's original thin diaphragm, the same basic principles are carried out in the operation of a modern cone loudspeaker. Most loudspeaker improvements over time have focused on the structure of the cone to get it to behave like a true piston over a variety of different frequencies and to eliminate resonance in the cone structure. Further, the use of specialized shapes of the cones themselves can be used to increase rigidity and improve their bending characteristics, which is ultimately the source of the pressure wave from their motion.

While cone loudspeakers can produce highly accurate sound reproduction, it is often necessary to have multiple cones, of multiple sizes, to produce balanced sound when a large range of sound waves needs to be reproduced. Single cones typically cannot provide a uniform response over a wide frequency range due to the inherent resonance from their mass and stiffness.

In recent years, a new technology in sound reproduction has arisen, the Distributed Mode Loudspeaker (commonly called a DML). In a DML, a flat panel is mechanically attached to a mechanical exciter which causes the panel to radiate acoustic energy equally from both sides and in a complex diffuse fashion due to the membrane being driven in phase over its whole surface. This basic concept is not new as it has been used by musical instruments for years. Sound panels in pianos and the sound boxes used in violins and other stringed instruments utilize this same property.

Some of the major benefits of a DML are the simplicity of construction and the wide frequency response. As opposed to a cone loudspeaker where the cone, which is often formed from paper, is best manufactured to highly complex geometries, the more mechanical nature of a DML simply requires a panel of material. While the exact composition of the panel can have great impact on the resultant sound (as has been repeatedly proven by the inability of modern instrument makers to reproduce the sound quality of a Stradivarius violin) the structure is still much simpler and more rugged. Further, because of how the sound is generated in a DML, a DML is typically able to produce a more uniform response over a much wider frequency range than a cone loudspeaker. This means DMLs often can be produced at a smaller size compared to cone loudspeakers while still reproducing excellent sound quality. A DML also typically has less directionality than a cone loudspeaker. In order to best hear the sound from a cone loudspeaker, the user must be appropriately positioned so that the pressure wave produced by the pistonic motion of the cone is directed toward them or is reflected off another surface before reaching them, depending on the sound desired. This is not required of a DML where oscillation of the entire panel produces the sound.

The panel nature of DMLs can also make them more suitable for certain applications than cones. For example, the panel of a DML can often be more easily incorporated into other devices than a cone because it doesn't have the specific size requirements and shielding needs of a cone. Further, the ability to alter the composition of the panel can allow for DMLs to be tailored to produce specific sound qualities which are particularly desired in certain applications. DMLs can also be used to provide for more sound over a wider area due to their decreased directionality.

DMLs can be particularly useful in areas where a relatively large volume of sound (e.g. volume above 70 dB) with a broad and balanced frequency response is desired. While there are many such applications, high volume sound spread over a wide area can be useful in, among other things, providing sounds (such as music or spoken word) in large areas such as outdoor arenas and amphitheaters, in environments where the produced sound must compete to be heard over ambient noise such as in loudspeaker systems used in noisy environments, in applications where the size requirements of many cone loudspeakers are simply not acceptable, such as in modern mobile devices, or in acoustic tools or weapons where particularly high volume sound can be used to cut or damage materials or even to kill or injure humans or other animals.

While DMLs are useful for all these applications, their simple construction can create unexpected problems. In typical construction, the mechanical exciter is simply attached to the panel such as via a strong adhesive and extends from the back of the panel. In order to operate correctly, the positioning is typically off-center to improve frequency response. The panel is then often supported in a simple frame to provide it with some form of partial enclosure to serve to hide the exciter(s) and to provide it with surfaces that are more easily attached to walls or other areas.

This simple structure provides for simplicity, but also has inherent weakness. The simple adhesive connection with the exciter extending from the generally planar panel makes the connection vulnerable to mechanical damage. This is particularly true should the exciter be exposed to a shear force (parallel to the panel) such as during transport. Regardless of the strength of the adhesive, as DMLs produce sounds from the entire panel, mechanical stress from the panel vibration can damage the adhesive and heat from the exciter when operated at high power draw can also result in damage to the exciter. Further, because the exciter is adhered to the panel, once the panel material has been selected, it can be difficult to alter it if slightly different tonal characteristics are desired from the DML later.

### SUMMARY OF THE INVENTION

The following is a summary of the invention in order to provide a basic understanding of some aspects of the invention. This summary is not intended to identify key or critical elements of the invention or to delineate the scope of the invention. The sole purpose of this section is to present some concepts of the invention in a simplified form as a prelude to the more detailed description that is presented later.

Because of these and other problems in the art, described herein is an assembly for a Distributed Mode Loudspeaker (DML), and the DML itself, which includes a free motion heat sink. The heat sink allows for heat dissipation from the exciters driving the panel to avoid damage to the exciters from excessive heat. Further, the heat sink can provide for mechanical reinforcement to the exciter connection to help resist shear forces while not impinging on the ability of the exciter to oscillate the panel in the desired fashion. Finally, the heat sink is positioned so that the panel may be provided with a flexible sleeve which allows for customization of the panel from an aesthetic point of view as well as for the alteration of specific tone production capabilities of the panel without the need to alter the panel construction or to disconnect the exciter or heat sink.

Described herein, among other things, is a distributed mode loudspeaker (DML) assembly comprising: a panel; an exciter adhered at a front of said exciter to a back of said panel; and a heat sink module including: a heat sink connected to said exciter on a back side of said exciter opposing said front side of said exciter; and a cover attached to said heat sink; wherein said heat sink can move longitudinally toward and away from said cover; and wherein, lateral motion of said exciter due to an external force being applied to said exciter is inhibited by said heat sink module.

In an embodiment of the DML assembly, the exciter is one of a plurality of exciters.

In an embodiment of the DML assembly, the plurality of exciters are all adhered at respective front sides to said back of said panel.

In an embodiment of the DML assembly, the plurality of exciters are all connected on respective back sides to said heat sink.

In an embodiment of the DML assembly, the cover inhibits lateral motion due to an external force of all said plurality of exciters.

In an embodiment of the DML assembly, the cover is formed of a major surface with a pair of flanges extending therefrom.

In an embodiment of the DML assembly, the major surface is perforated.

In an embodiment of the DML assembly, the flanges extend longitudinally from said major surface of said cover toward said panel.

In an embodiment of the DML assembly, the panel is generally rectilinear in shape.

In an embodiment of the DML assembly, the panel is comprised of a foil faced foam board.

In an embodiment of the DML assembly, the heat sink is connected to said exciter via a screw.

In an embodiment, the DML assembly further comprises a sleeve into which said panel is placed.

In an embodiment of the DML assembly, the sleeve includes an opening corresponding to a location of said heat sink module.

In an embodiment, the DML assembly further comprises a frame about a periphery of said panel, said frame pinching said sleeve between said frame and said panel.

In an embodiment, the DML assembly further comprises a frame about a periphery of said panel.

In an embodiment of the DML assembly, the cover is attached to said frame.

In an embodiment of the DML assembly, the DML assembly is configured to generated sound of volume above 70 dB.

In an embodiment of the DML assembly, the DML assembly is configured to generated sound of volume above 80 dB.

In an embodiment of the DML assembly, the DML assembly is configured to generated sound of volume above 100 dB.

In an embodiment of the DML assembly, electronics for driving said exciter are mounted on said heat sink.

### BRIEF DESCRIPTION OF THE DRAWINGS

FIG. 1 shows an exploded view of the major components of a Distributed Mode Loudspeaker (DML) showing the location of the exciter module.

FIG. 2 shows an exploded view of the DML of FIG. 1 with additional visible detail on the exciters and exciter module.

### DESCRIPTION OF THE PREFERRED EMBODIMENT(S)

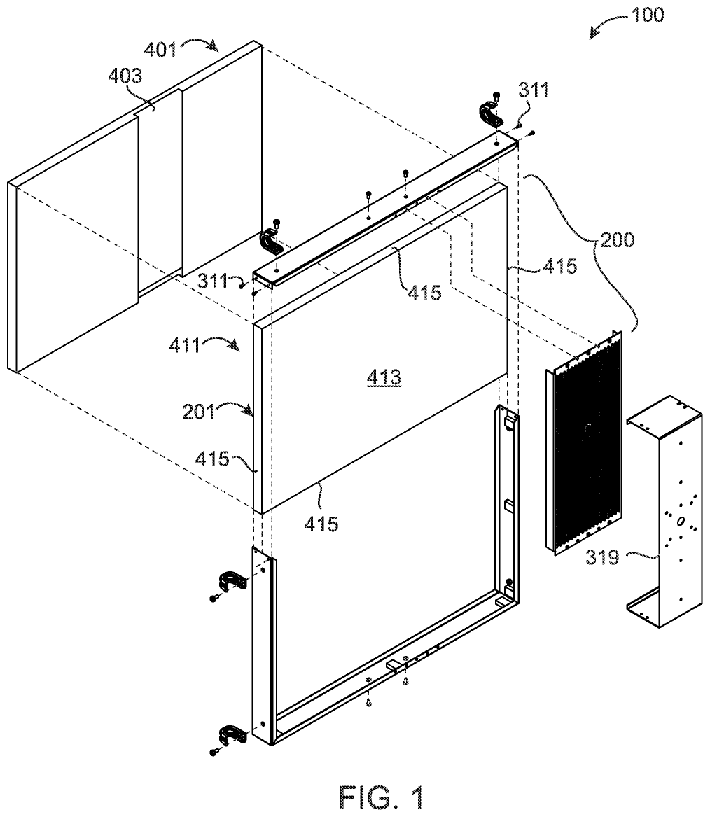

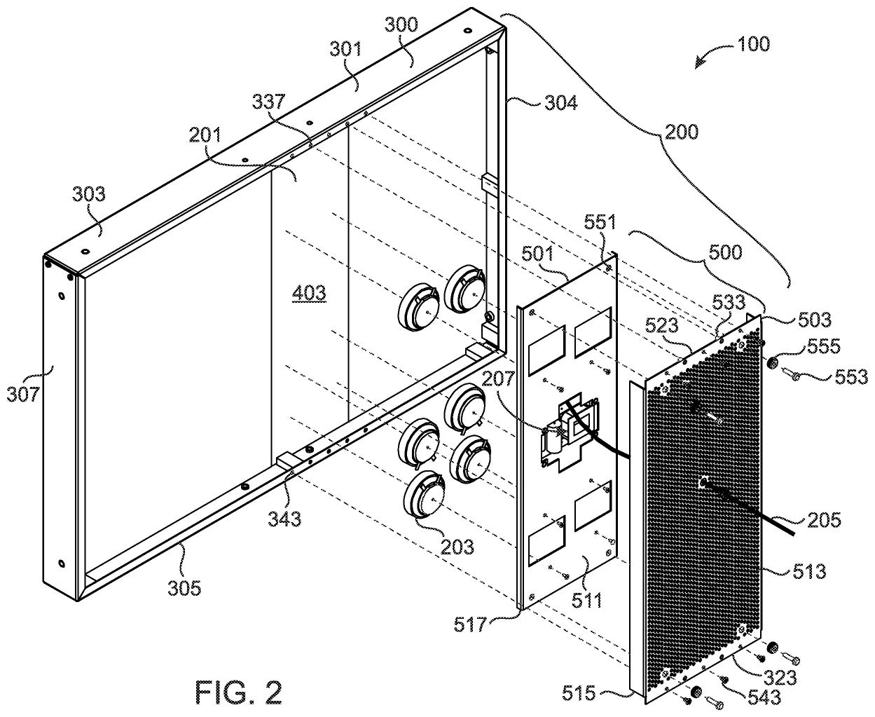

FIGS. 1 and 2 provide for two different exploded images of a Distributed Mode Loudspeaker (DML) and enclosure device (100). The loudspeaker component (200) comprises the typical elements of a DML including a panel (201), which in the depicted embodiment is generally in the shape of a rectangular parallelepiped having two major surfaces (the front (411) and back (413)) and four minor surfaces forming the edges (415) but that is by no means required, and one or more exciters (203). The panel may comprise any material useable as the panel (201) in a DML assembly and in the depicted embodiment comprises a foil faced foam board. The exciters (203) will typically be generally rigidly attached to the back (403) of the panel (201), such as via a high strength adhesive, at a location off center of the panel (201) as is understood by one of ordinary skill in the art. In the depicted embodiment, there are multiple exciters (203) used and six are specifically depicted. This number may be preferred in certain high volume applications, for example, above 70 dB, above 80 dB, above 90 dB, or above 100 dB applications as multiple exciters driven together can more easily induce greater mechanical motion on the panel (201) and, thus, volume, but such number is by no means required. Increased heat dispersion in the exciters also allows for increased power. The loudspeaker (200) component also includes appropriate wiring (205) and/or electronics (207) to drive the various exciters (203) or otherwise interface the device (100) with associated electronics.

The enclosure (300) component generally comprises a frame (301) which is generally in a form corresponding to the perimeter shape of the panel (201) and in the depicted embodiment includes a top (303) and then a generally “U”-shaped lower component formed from a bottom (305), left side (307) and right side (309). Once assembled, the frame (301) is of generally rectangular shape and surrounds and contacts the perimeter of the panel (201). Specifically, the enclosure goes around and corresponds to the sides (415) of the panel (201) serving as a frame while keeping the front (411) and back (413) of the panel (201) open.

The pieces (303), (305), (307) and (309) are typically connected together via screws (311), adhesive, other connectors, or combinations of connectors to form the frame (301). The enclosure (300) may also include an optional mounting bracket (319) which may be used to help support the heat sink module (500) or reinforce the interconnection of the heat sink module (500) to the frame (301). However, the mounting bracket (319) will typically solely be used to assist in mounting the device (100) to an external surface such as, but not limited to, a wall.

In order to provide for an alterable aesthetic appearance, as well as to alter the specific acoustic response received from the panel (201), the panel (201) may be placed within a cover which in the depicted embodiment is a fabric sleeve (401). The sleeve (401) is generally in the form of a hollow parallelepiped of generally the same inner volume as the volume of the panel (201) and includes an opening (403) which leaves a portion of the back (413) of the panel (201) exposed around the area where the exciters (203) are attached and generally conforming to the shape of the heat sink module (500). The sleeve (401) will typically completely cover the front (411) of the panel (201) and also enclose all the sides (415) simply for ease of connection. In this way, the sleeve (401) serves effectively to enclose the panel (201) in the form of a sock or similar structure, but this is not required. The sleeve (401) is generally intended to be readily and repeatedly removable from the panel (201) without damage to the sleeve (401) or panel (201) by placement of the panel (201) into the interior volume of the sleeve (401).

The sleeve (401) may be constructed from any material, but will preferably be constructed of a flexible material such as, but not limited to, a fabric. The sleeve (401) will be placed over the panel (201) usually by placing one end (415) of the panel (201) through the opening (403) in the sleeve (401), arranging the end (415) to be in close proximity to the inner surfaces of the sleeve (401) and to be aligned with the shape of the inner volume of the sleeve (401). The same process is then typically repeated for the other end. The exciters (203) and heat sink module (500) will then generally be positioned to correspond to the opening (403) in the sleeve (401) and extend through the opening (403) from the inner volume to an external area. Typically the panel (201) will be placed in the sleeve (401) before the panel (201) is surrounded by the frame (301). The frame (301) can, thus, be used to additionally hold the sleeve (401) in place by pinching the sleeve (401) material arranged at the perimeter of the panel (201) between the frame (301) and the panel (201). The geometry of the sleeve (401) may also assist with positioning and securing the sleeve (401) to the panel (201).

The sleeve (401) will typically be designed to provide aesthetic appeal to the panel (201). Specifically, the sleeve (401) may be made in any color and may have imagery printed thereon so that the front of the device (100) may include logos, images, text, or other visual representations. The material, structure, and or shape of the sleeve (401) may also be selected to provide the panel with additional tonal, volume, or other sonic qualities. Further, the sleeve may be printed, impregnated, plated, or otherwise modified with additional materials to alter such qualities. Typically, the sleeve may act as a specific dampener or may have areas of different construction to alter the panel's (201) directionality of wave production but these options are by no means required or exhaustive of any application. In some embodiments, the sleeve (401) will be designed to fit tightly or snuggly on the panel (201) and may even need to be stretched in order to fully accommodate the panel (201). In such a case, the frame (301) may help serve to keep the sleeve (401) from coming loose from the panel (201) or changing position thereon. In alternative embodiments, the sleeve (401) may fit more loosely which may serve to alter the shape of the panel (201) or even conceal its size or shape from viewing.

In the depicted embodiment of FIGS. 1 and 2, the exciters (203) are connected to a heat sink module (500) which includes a heat sink (501) and cover (503). The exciters (203) are mounted to the heat sink (501) which is typically rectangular (but may be any shape) and will typically be constructed of a generally rigid material known by one of ordinary skill in the art as being suitable as a heat sink. The exciters (203) will generally be rigidly attached to the heat sink (501) such as, but not limited to, things such as screws, bolts, adhesives, and combinations thereof. In the depicted embodiment, this is via a single screw which is attached to the back of the exciter. The connection between the heat sink (501) and the exciter (203) will serve to allow for heat generated by the exciter (203) to be readily passed into the heat sink (501). The large surface area of the heat sink (501) (which will commonly extend generally the height of the panel (201)) compared to the contact area with the exciters (203), allows for the generated heat to be distributed and then dissipated to ambient air quicker than heat from the exciters (203) can be dissipated without the heat sink (501) being present. It should be noted that in the depicted embodiment air flow over the heat sink (501) is based solely on convection. However, that is by no means required and the device (100) may include fans or related objects to increase air flow over the heat sink (501).

The heat sink (501) may also serve to mount electronics (207) related to the driving of the exciters (203) or other electronic components of the device (100). Any type of electronics may be mounted on the heat sink (501) including, but not limited to, digital processors, wireless transceivers, analog or digital input amplifiers, crossover networks, line matching transformers, and/or memory. Mounting electronics (207) on the heat sink (501) also allows for any heat generated by the electronics (207) to also be dissipated via the heat sink (501) which may be desirable depending on the nature of the electronics.

The heat sink (501) is typically used with a cover (503). The cover (503) is typically metal and is perforated or otherwise structured so as to have a permeated structure at least on it's major surface (513). The cover (503) may also or alternatively be made of a heat sink material or have other structure to allow heat being dissipated from the heat sink (501) to be easily dissipated through the cover (503). The cover (503) will typically comprise a major surface (513) which is generally of similar size, but slightly larger to the size of the major surface (511) of the heat sink (501). The cover (503) major surface (513) will typically be spaced from the major surface (511) of the heat sink (501) to provide for free motion in a direction perpendicular to the major surfaces (513) and (511) with the specific positioning often depending on air flow characteristics around the heat sink (501) and the mechanical motion of the exciters (203). The cover (503) will generally not include any form of heat displacement with heat from the heat sink (501) simply passing through the perforated surface, but this is by no means required. The cover (503) will typically include at least one extended mounting tab (523) which extends from the major surface and/or includes holes and associated screws (543) and/or mounted pins (533) to connect with corresponding holes (343) and (333) on the frame (301).

When connected to the frame (301), the cover (503) will typically serve to generally cover the heat sink and the exciters (203) and is attached to the frame (301). The heat sink is also typically attached to the cover via a load screw (553) and an anti-vibration bushing (555). The load screw (553) is arranged to go into a corresponding hole and anti-vibration nut (551) in the heat sink (501). This connection is typically not rigid, but is arranged so that the heat sink (501) can move longitudinally (toward and away from the panel (201) and the cover (503)) but cannot move any substantial amount laterally relative to either.

To further inhibit lateral motion of the heat sink (501), the cover (503) will also typically include a pair of flanges (515) which extend generally perpendicular from the major surface (513) along the side of the heat sink (501). The heat sink (501) may include corresponding parallel flanges (517) but that is by no means required. Interaction of the flanges (515) with the sides of the flanges (501) or with the flanges (517) is such that the heat sink (501) generally cannot move any substantial amount parallel to the major surface (513) of the cover (503) as such motion is inhibited by contact between flanges (517) and flanges (515). The flanges (517) and (515) are primarily designed simply to provide their connected structures with improved strength.

Once assembled, the heat sink module (500) effectively covers the exciters (203) and acts to protect them from shear forces. Further, as the heat sink module (500) is attached to the frame (301), the device (100) is provided with a relatively rectilinear parallelepiped rigid exterior shape which can make shipping and mounting easier.

While the invention has been disclosed in conjunction with a description of certain embodiments, including those that are currently believed to be the preferred embodiments, the detailed description is intended to be illustrative and should not be understood to limit the scope of the present disclosure. As would be understood by one of ordinary skill in the art, embodiments other than those described in detail herein are encompassed by the present invention. Modifications and variations of the described embodiments may be made without departing from the spirit and scope of the invention.

It will further be understood that any of the ranges, values, properties, or characteristics given for any single component of the present disclosure can be used interchangeably with any ranges, values, properties, or characteristics given for any of the other components of the disclosure, where compatible, to form an embodiment having defined values for each of the components, as given herein throughout. Further, ranges provided for a genus or a category can also be applied to species within the genus or members of the category unless otherwise noted.

Finally, the qualifier “generally,” and similar qualifiers as used in the present case, would be understood by one of ordinary skill in the art to accommodate recognizable attempts to conform a device to the qualified term, which may nevertheless fall short of doing so. This may be because related terms are purely geometric constructs having no real-world equivalent (for example, no sphere is every perfectly spherical), or there may be other reasons why a given term may be more precise than its real-world equivalent. Variations from geometric, mathematical, and other descriptions are unavoidable due to, among other things, manufacturing tolerances resulting in shape variations, defects and imperfections, non-uniform thermal expansion, and natural wear. Moreover, there exists for every object a level of magnification at which geometric, mathematical, and other precise descriptors fail, due to the nature of matter. One of ordinary skill would thus understand the term “generally” and relationships contemplated herein, regardless of the inclusion of such qualifiers to include a range of variations from the literal geometric, mathematic, or other meaning of the term in view of these and other considerations.

1. A distributed mode loudspeaker (DML) assembly comprising:
a panel;
an exciter adhered at a front of said exciter to a back of said panel; and
a heat sink module including:
a heat sink connected to said exciter on a back side of said exciter opposing said front side of said exciter; and
a cover attached to said heat sink;
wherein said heat sink can move longitudinally toward and away from said cover; and
wherein, lateral motion of said exciter due to an external force being applied to said exciter is inhibited by said heat sink module.

2. The DML assembly of claim 1, wherein said exciter is one of a plurality of exciters.

3. The DML assembly of claim 2, wherein said plurality of exciters are all adhered at respective front sides to said back of said panel.

4. The DML assembly of claim 3, wherein said plurality of exciters are all connected on respective back sides to said heat sink.

5. The DML assembly of claim 4, wherein said cover inhibits lateral motion due to an external force of all said plurality of exciters.

6. The DML assembly of claim 1, wherein electronics for driving said exciter are mounted on said heat sink.

7. The DML assembly of claim 1, wherein said cover is formed of a major surface with a pair of flanges extending therefrom.

8. The DML assembly of claim 7, wherein said major surface is perforated.

9. The DML assembly of claim 7, wherein said flanges extend longitudinally from said major surface of said cover toward said panel.

10. The DML assembly of claim 1, wherein said panel is generally rectilinear in shape.

11. The DML assembly of claim 1, wherein said panel is comprised of a foil faced foam board.

12. The DML assembly of claim 1, wherein said heat sink is connected to said exciter via a screw.

13. The DML assembly of claim 1 further comprising a sleeve into which said panel is placed.

14. The DML assembly of claim 13, wherein said sleeve includes an opening corresponding to a location of said heat sink module.

15. The DML assembly of claim 13 further comprising a frame about a periphery of said panel, said frame pinching said sleeve between said frame and said panel.

16. The DML assembly of claim 1 further comprising a frame about a periphery of said panel.

17. The DML assembly of claim 16, wherein said cover is attached to said frame.

18. The DML assembly of claim 1, wherein said DML assembly is configured to generated sound of volume above 70 DB.

19. The DML assembly of claim 1, wherein said DML assembly is configured to generated sound of volume above 80 DB.

20. The DML assembly of claim 1, wherein said DML assembly is configured to generated sound of volume above 100 DB.
